(19) United States
(12) Patent Application Publication
(10) Pub. No.: US 2015/0366066 A1
(43) Pub. Date: Dec. 17, 2015

(54) SUBSTRATE WITH ELECTRONIC DEVICE EMBEDDED THEREIN AND MANUFACTURING METHOD THEREOF

(71) Applicant: SAMSUNG ELECTRO-MECHANICS CO., LTD., Suwon-Si (KR)

(72) Inventors: Tae-Seong KIM, Suwon-Si (KR); Yeon-Seop YU, Suwon-Si (KR); Bok-Hee LEE, Suwon-Si (KR)

(21) Appl. No.: 14/528,804

(22) Filed: Oct. 30, 2014

(30) Foreign Application Priority Data
Jun. 17, 2014 (KR) 10-2014-0073584

(51) Int. Cl. H05K 1/18; H05K 3/00; H05K 3/30

(52) U.S. Cl. CPC H05K 1/182; H05K 3/30; H05K 3/0026; H05K 2201/10015; H05K 2201/1003

(57) ABSTRACT

An electronic device embedded substrate and a method of manufacturing the same are disclosed. The electronic device embedded substrate in accordance with an aspect of the present invention includes: an electronic device; and a core substrate having a cavity, in which the electronic device is embedded and of which a width of at least a portion is smaller than widths of other portions thereof.

### CROSS-REFERENCE TO RELATED APPLICATIONS

This application claims the benefit of Korean Patent Application No. 10-2014-0073584, filed with the Korean Intellectual Property Office on Jun. 17, 2014, the disclosure of which is incorporated herein by reference in its entirety.

### BACKGROUND

1. Technical Field

The present invention relates to an electronic device embedded substrate and a manufacturing method thereof.

2. Background Art

In the conventional electronics manufacturing industry, most active/passive elements have been mounted over a substrate by use of the surface mount technology (SMT). However, in step with the electronic products that have been increasingly smaller, new packing technologies have been developed to embed the active/passive elements in the substrate.

In the case of active/passive element embedded substrate products, economical manufacturing processes are possible by integrating various active/passive elements in organic substrates, and the module products utilizing this packaging technology can contribute to making the products smaller.

As such, in order to produce an embedded substrate by embedding an electronic device in a substrate, it is necessary to process a cavity, which is a space for embedding the electronic device in the substrate.

Although forming a large cavity would be advantageous for embedding the electronic device in the cavity, forming the cavity excessively too large could cause problems such as a defective via or misalignment of the embedded electronic device.

The related art of the present invention is disclosed in Korea Patent Publication No. 10-2014-0016081 (laid open on Feb. 7, 2014).

### SUMMARY

Some embodiments of the present invention provide an electronic device embedded substrate that can effectively prevent misalignment of an electronic device embedded in a core substrate.

An aspect of the present invention provides an electronic device embedded substrate, which includes: an electronic device; and a core substrate having a cavity, in which the electronic device is embedded and of which a width of at least a portion is smaller than widths of other portions thereof.

Here, the cavity can be formed in such a way that a middle portion thereof is curved and protruded toward the electronic device on a plane of the core substrate.

The middle portion of the cavity can be protruded toward the electronic device, when the core substrate is viewed cross-sectionally.

The cavity can be formed by having a lower portion thereof protruded toward the electronic device, when the core substrate is viewed cross-sectionally.

Another aspect of the present invention provides a method of manufacturing an electronic device embedded substrate that includes: preparing a core substrate; forming a cavity in the core substrate in such a way that a width of at least a portion of the cavity is smaller than widths of other portions of the cavity; and embedding an electronic device in the cavity.

Here, the step of forming a cavity can include laser-processing the core substrate in such a way that a middle portion of the cavity is curved and protruded on a plane of the core substrate.

The step of laser-processing the core substrate can include: processing the core substrate in such a way that a slope is formed cross-sectionally from one surface of the core substrate to the middle portion thereof; and processing the core substrate in such a way that a slope is formed cross-sectionally from the other surface of the core substrate to the middle portion thereof.

The step of laser-processing the core substrate can include processing the core substrate in such a way that a slope is formed from one surface of the core substrate to the other surface of the core substrate.

### BRIEF DESCRIPTION OF THE DRAWINGS

FIG. 1 is a top view showing an electronic device embedded substrate in accordance with an embodiment of the present invention.

FIG. 2 is a cross-sectional view showing the electronic device embedded substrate in accordance with an embodiment of the present invention.

FIG. 3 is a cross-sectional view showing an electronic device embedded substrate in accordance with another embodiment of the present invention.

FIG. 4 is a flow diagram showing a method of manufacturing an electronic device embedded substrate in accordance with an embodiment of the present invention.

FIG. 5 is a flow diagram showing a method of manufacturing an electronic device embedded substrate in accordance with another embodiment of the present invention.

### DETAILED DESCRIPTION

Hereinafter, an electronic device embedded substrate and a method of manufacturing the same in accordance with certain embodiments of the present invention will be described in detail with reference to the accompanying drawings. In describing the present invention with reference to the accompanying drawings, any identical or corresponding elements will be assigned with same reference numerals, and no redundant description thereof will be provided.

When one element is described to be “coupled” to another element, it does not refer to a physical, direct contact between these elements only, but it shall also include the possibility of yet another element being interposed between these elements and each of these elements being in contact with said yet another element.

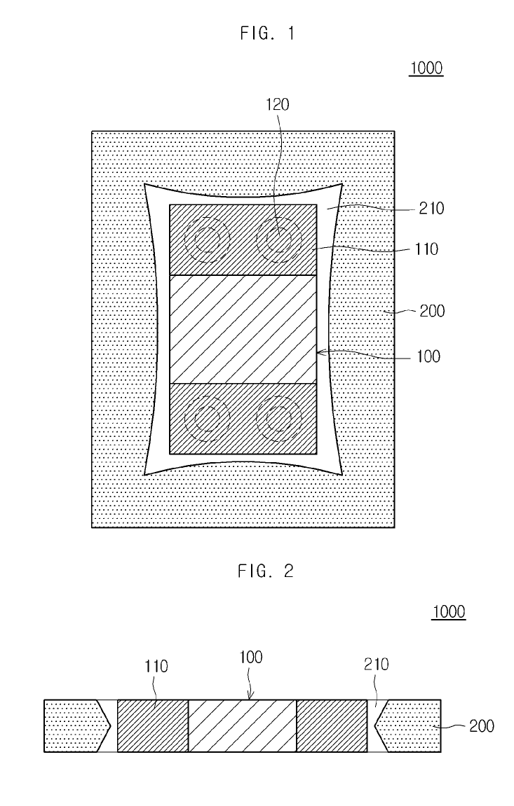

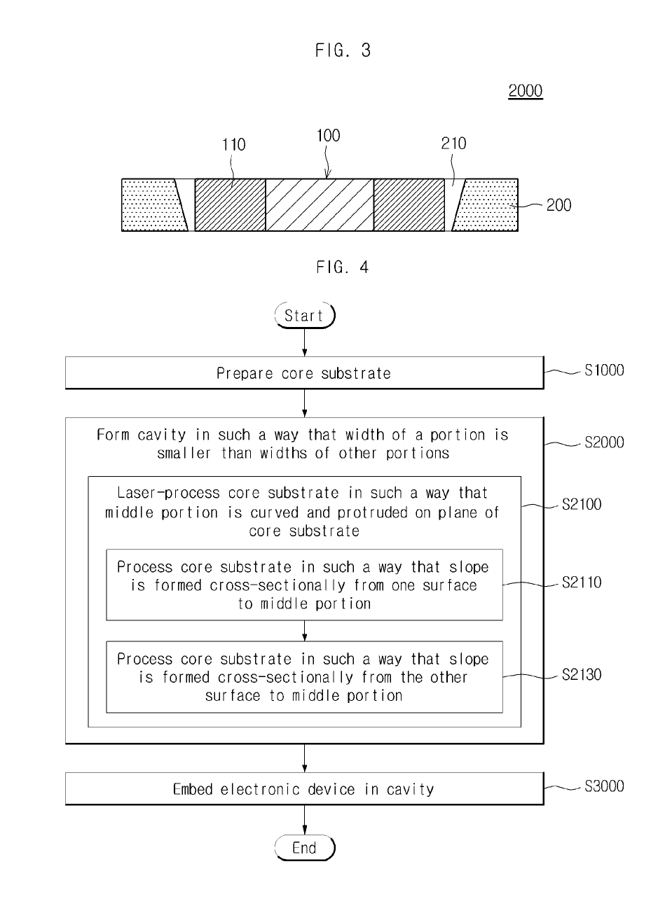

FIG. 1 is a top view showing an electronic device embedded substrate in accordance with an embodiment of the present invention. FIG. 2 is a cross-sectional view showing the electronic device embedded substrate in accordance with an embodiment of the present invention.

As illustrated in FIG. 1 and FIG. 2, an electronic device embedded substrate 1000 in accordance with an embodiment of the present invention includes an electronic device 100 and a core substrate 200.

The electronic device 100, which is an active element or a passive element embedded in a cavity 210 formed in the core substrate 200, can be an active element such as an IC chip or a passive element such as a capacitor, an inductor or the like.

Here, the electronic device 100 can have electrodes 110 formed at some portions thereof, with vias 120 formed in the electrodes 110, as shown in FIG. 1 and FIG. 2, but this is merely an example of the electronic device 100 for the convenience of description, and the present invention is not limited to what is illustrated herein and can be modified variously as necessary.

The core substrate 200 includes the cavity 210, in which the electronic device 100 is embedded, and can have a specific circuit pattern formed thereon. The core substrate 200 can be formed in such a way that a width of at least a portion of the cavity 210 is smaller than widths of other portions of the cavity 210. Here, the cavity 210, which is a space for embedding the electronic device 100 in the core substrate 200, can be formed by a punching method using a CNC drill or a metallic mold or a drilling method using laser (CO₂ or YAG).

The cavity 210 can be formed to correspond to an external shape of the electronic device 100 and in such a way that a width of the cavity 210 is greater than that of the electronic device 100 in order to allow the electronic device 100 to be embedded readily.

However, if the width of the cavity 210 were formed to have an excessively larger width than that of the electronic device 100, it might result in a misalignment, for example, twisted positioning of the electronic device 100 in the cavity 210.

Moreover, this misalignment of the electronic device 100 may weaken a joining portion of the via 120 or cause a plating dimple due to an uneven via shape.

Accordingly, as described above, the electronic device embedded substrate 1000 in accordance with an embodiment of the present invention is formed in such a way that the width of at least a portion of the cavity 210 is smaller than the widths of other portions of the cavity 210 so that the misalignment of the electronic device 100 embedded in the core substrate 200 is effectively prevented while allowing the electronic device 100 to be embedded readily.

That is, as shown in FIG. 1 and FIG. 2, a portion of the cavity 210 having the narrowest width supports lateral surfaces of the electronic device 100 to prevent the misalignment of the electronic device 100, and the remaining portions of the cavity 210 provide a predetermined gap to the electronic device 100 in order to allow the electronic device 100 to be embedded readily.

In the electronic device embedded substrate 1000 in accordance with the present embodiment, the cavity 210 can be formed in such a way that a middle portion thereof is curved and protruded toward the electronic device 100 on a plane of the core substrate 200. Here, “curved and protruded” refers to being protruded in the bent shape of a bow.

Specifically, as shown in FIG. 1, the cavity 210 can be formed in such a way that the cavity 210 is narrowest at the middle portion thereof and becomes wider toward vertices thereof, when the core substrate 200 is viewed from the top.

Accordingly, an area of the cavity 210 is reduced in a direction for preventing the electronic device 100 from moving, and thus movement of the electronic device 100 within the cavity 210 can be effectively prevented.

Moreover, since a stress exerted to an inner wall of the core substrate 200, in which the cavity 210 is formed, by a force of the moving electronic device 100 can be dispersed, a rigidity of the core substrate 200 can be enhanced.

Although it is illustrated in FIG. 1 that the middle portions of the cavity 210 are curved and protruded toward every lateral direction of the electronic device 100, the present invention is not limited to what is illustrated herein, and, if necessary, it is possible that the middle portion of the cavity 210 only in the direction for preventing the electronic device 100 from moving is curved and protruded.

For example, in order to process the vias 120 precisely in the electrode 110 of the electronic device 100, it is necessary that a portion of the electronic device 100 in which the electrode 110 is formed be more strictly prevented from moving.

Therefore, in such a case, the middle portion of the cavity 210 may be curved and protruded in the direction of the electrode 110 of the electronic device 100, and other portions of the cavity 210 may be formed to be flat.

Here, the middle portion of the cavity 210 can be protruded toward the electronic device 100, when the core substrate 200 is viewed cross-sectionally.

Specifically, as illustrated by the cross-sectional view of the core substrate 200 in FIG. 2, the cavity 210 can be protruded in such a way that the narrowest width is formed at the middle portion thereof and formed in such a way that the width of the cavity 210 increases toward top and bottom surfaces of the core substrate 200.

Accordingly, the protruded portions of the cavity 210 can support the electronic device 100 stably without being exposed above or below the core substrate 200 and can effectively prevent lateral-direction displacement as well as longitudinal-direction displacement of the electronic device 100.

FIG. 3 is a cross-sectional view showing an electronic device embedded substrate in accordance with another embodiment of the present invention.

As shown in FIG. 3, in an electronic device embedded substrate 2000 in accordance with another embodiment of the present invention, a cavity 210 can be formed by having a lower portion thereof protruded toward an electronic device 100, when a core substrate 200 is viewed cross-sectionally.

Specifically, as illustrated by the cross-sectional view of the core substrate 200 in FIG. 3, the cavity 210 can be protruded in such a way that a narrowest width is formed at the lower portion thereof and formed in such a way that a width of the cavity 210 increases toward a top surface of the core substrate 200.

Accordingly, the electronic device 100 can be slid down along sloped surfaces of the cavity 210 when the electronic device 100 is embedded in the cavity 210, and thus the electronic device 100 can be embedded more readily in the core substrate 200.

Other than the elements described above, most major elements of the electronic device embedded substrate 2000 in accordance with another embodiment of the present invention are identical or similar to those of the electronic device embedded substrate 1000 in accordance with an embodiment of the present invention and thus will not be redundantly described herein.

FIG. 4 is a flow diagram showing a method of manufacturing an electronic device embedded substrate in accordance with an embodiment of the present invention. Here, for the convenience of description, every element expressed in the method of manufacturing an electronic device embedded substrate in accordance with an embodiment of the present invention will be described with reference to FIG. 1 and FIG. 2.

As shown in FIG. 4, the method of manufacturing an electronic device embedded substrate in accordance with an embodiment of the present invention starts with preparing a core substrate 200 (S1000). Here, the core substrate 200, which is a main body that constitutes an external appearance of the electronic device embedded substrate in accordance with the present embodiment, can have a specific circuit pattern formed thereon.

Then, a cavity 210 can be formed in the core substrate 200 in such a way that a width of at least a portion of the cavity 210 is smaller than widths of other portions of the cavity 210 (S2000). Here, the cavity 210, which is a space for embedding an electronic device 100 in the core substrate 200, can be formed by a punching method using a CNC drill or a metallic mold or a drilling method using laser (CO₂ or YAG).

Thereafter, the electronic device 100 can be embedded in the cavity 210 (S3000). Here, the electronic device 100, which is an active element or a passive element embedded in the cavity 210 formed in the core substrate 200, can be an active element such as an IC chip or a passive element such as a capacitor, an inductor or the like.

Moreover, as shown in FIG. 1 and FIG. 2, the electronic device 100 can have an electrode 110 formed at one portion thereof, and a via 120 can be formed in the electrode 110.

The cavity 210 can be formed so as to correspond to the external appearance of the electronic device 100 and in such a way that a width of the cavity 210 is greater than that of the electronic device 100 in order to allow the electronic device 100 to be embedded readily.

Nevertheless, if the width of the cavity 210 were excessively larger than that of the electronic device 100, misalignment might occur, for example, positioning of the electronic device 100 in the cavity 210 might be twisted.

Moreover, this misalignment of the electronic device 100 may weaken a joining portion of the via 120 or cause a plating dimple due to an uneven via shape.

Accordingly, as described above, in the method of manufacturing an electronic device embedded substrate in accordance with the present embodiment, the cavity 210 is formed in such a way that the width of at least a portion of the cavity 210 is smaller than the widths of other portions of the cavity 210 so that the misalignment of the electronic device 100 embedded in the core substrate 200 is effectively prevented while allowing the electronic device 100 to be embedded readily.

In the method of manufacturing an electronic device embedded substrate in accordance with the present embodiment, the S2000 step can include laser-processing the core substrate 200 in such a way that a middle portion thereof is curved and protruded on a plane of the core substrate 200 (S2100).

That is, as shown in FIG. 1, the cavity 210 can be formed in such a way that the cavity 210 is narrowest at the middle portion thereof and becomes wider toward vertices thereof, when the core substrate 200 is viewed from the top.

Accordingly, an area of the cavity 210 is reduced in a direction for preventing the electronic device 100 from moving, and thus movement of the electronic device 100 within the cavity 210 can be effectively prevented.

Moreover, since a stress exerted to an inner wall of the core substrate 200, in which the cavity 210 is formed, by a force of the moving electronic device 100 can be dispersed, a rigidity of the core substrate 200 can be enhanced.

In such a case, the above-described shape of cavity 210 can be processed by changing a trajectory of a laser drill in the process data for the laser-processing of the core substrate 200.

Here, the S2100 step can include: processing the core substrate 200 in such a way that a slope is formed cross-sectionally from one surface of the core substrate 200 to the middle portion thereof (S2110); and processing the core substrate 200 in such a way that a slope is formed cross-sectionally from the other surface of the core substrate 200 to the middle portion thereof (S2130).

That is, as illustrated by the cross-sectional view of the core substrate 200 in FIG. 2, the cavity 210 can be protruded in such a way that the narrowest width is formed at a middle portion thereof and formed in such a way that the width of the cavity 210 increases toward top and bottom surfaces of the core substrate 200.

Accordingly, the protruded portions of the cavity 210 can support the electronic device 100 stably without being exposed above or below the core substrate 200 and can effectively prevent lateral-direction displacement as well as longitudinal-direction displacement of the electronic device 100.

In such a case, the laser-processing of the core substrate 200 can be made by processing the core substrate 200 cross-sectionally to the middle portion only by adjusting the intensity of the laser irradiated from the one surface of the core substrate 200, and then by processing the core substrate 200 cross-sectionally to the middle portion only by properly adjusting the intensity of the laser irradiated from the other surface of the core substrate 200.

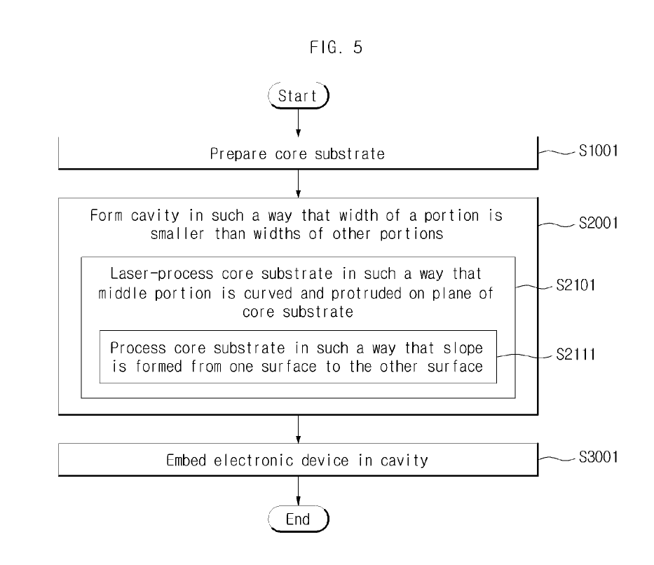

FIG. 5 is a flow diagram showing a method of manufacturing an electronic device embedded substrate in accordance with another embodiment of the present invention. Here, for the convenience of description, every element expressed in the method of manufacturing an electronic device embedded substrate in accordance with another embodiment of the present invention will be described with reference to FIG. 3.

As shown in FIG. 5, in the method of manufacturing an electronic device embedded substrate in accordance with another embodiment of the present invention, the step of laser-processing a core substrate 200 (S2101) can include processing the core substrate 200 in such a way that a slope is formed from one surface of the core substrate 200 to the other surface of the core substrate 200 (S2111).

That is, as illustrated by the cross-sectional view of the core substrate 200 in FIG. 3, a cavity 210 can be protruded in such a way that a narrowest width is formed at a lower portion thereof and formed in such a way that a width of the cavity 210 increases toward a top surface of the core substrate 200.

Accordingly, an electronic device 100 can be slid down along sloped surfaces of the cavity 210 when the electronic device 100 is embedded in the cavity 210, and thus the electronic device 100 can be embedded more readily in the core substrate 200.

In such a case, the laser-processing of the core substrate 200 can be made all the way to the other surface of the core substrate 200 by properly adjusting the intensity of the laser irradiated to the one surface of the core substrate 200.

Other than the step described above, most major configurations of the method of manufacturing an electronic device embedded substrate in accordance with another embodiment of the present invention are identical or similar to those of the method of manufacturing an electronic device embedded substrate in accordance with an embodiment of the present invention and thus will not be redundantly described herein.

Although certain embodiments of the present invention have been described hitherto, it shall be appreciated that the present invention can be variously modified and permutated by those of ordinary skill in the art to which the present invention pertains by supplementing, modifying, deleting and/or adding an element without departing from the technical ideas of the present invention, which shall be defined by the claims appended below. It shall be also appreciated that such modification and/or permutation are also included in the claimed scope of the present invention.

What is claimed is:

1. An electronic device embedded substrate comprising:
an electronic device; and
a core substrate having a cavity therein, the electronic device being embedded in the cavity, a width of at least a portion of the cavity being smaller than widths of other portions of the cavity.

2. The electronic device embedded substrate of claim 1, wherein the cavity is formed in such a way that a middle portion thereof is curved and protruded toward the electronic device on a plane of the core substrate.

3. The electronic device embedded substrate of claim 2, wherein the middle portion of the cavity is protruded toward the electronic device, when the core substrate is viewed cross-sectionally.

4. The electronic device embedded substrate of claim 2, wherein the cavity is formed by having a lower portion thereof protruded toward the electronic device, when the core substrate is viewed cross-sectionally.

5. A method of manufacturing an electronic device embedded substrate, comprising:
preparing a core substrate;
forming a cavity in the core substrate in such a way that a width of at least a portion of the cavity is smaller than widths of other portions of the cavity; and
embedding an electronic device in the cavity.

6. The method of claim 5, wherein the step of forming a cavity comprises laser-processing the core substrate in such a way that a middle portion of the cavity is curved and protruded on a plane of the core substrate.

7. The method of claim 6, wherein the step of laser-processing the core substrate comprises:
processing the core substrate in such a way that a slope is formed cross-sectionally from one surface of the core substrate to the middle portion thereof; and
processing the core substrate in such a way that a slope is formed cross-sectionally from the other surface of the core substrate to the middle portion thereof.

8. The method of claim 6, wherein the step of laser-processing the core substrate comprises processing the core substrate in such a way that a slope is formed from one surface of the core substrate to the other surface of the core substrate.
